(19) United States
(12) Patent Application Publication
(10) Pub. No.: US 2026/0248035 A1
(43) Pub. Date: Aug. 20, 2026

(54) ELECTRONIC DEVICE

(71) Applicant: Advanced Semiconductor Engineering, Inc., Kaohsiung (TW)

(72) Inventors: Ying-Chung CHEN, New Taipei City (TW); Hsin-Ying HO, Taoyuan (TW)

(73) Assignee: Advanced Semiconductor Engineering, Inc., Kaohsiung (TW)

(21) Appl. No.: 19/054,711

(22) Filed: Feb. 14, 2025

(51) Int. Cl. H01L 25/16; G02B 6/42; H01L 23/373; H01L 23/538; H04B 10/40; H10F 55/00

(52) U.S. Cl. CPC H10W 90/00; G02B 6/4246; G02B 6/4268; H10F 55/00; H10W 70/611; H10W 90/401; H04B 10/40; H10W 40/25

(57) ABSTRACT

The present disclosure provides an electronic device. The electronic device includes an electronic component, an optical transceiver disposed over the electronic component, and an interposer disposed between the electronic component and the optical transceiver. The interposer is configured to reduce thermal interference to the optical transceiver.

### BACKGROUND

### 1. Technical Field

The present disclosure relates to an electronic device.

### 2. Description of the Related Art

Optical component arrays (e.g., LEDs and photodiodes) can be provided on an integrated circuit (IC) to minimize electrical path length and reduce package size. However, to achieve the necessary bandwidth for optical signal transmission, an increase in optical channels and IC size is required, leading to higher manufacturing costs and reduced yield. Additionally, heat generated by the IC can adversely affect the performance and efficiency of the optical components.

### SUMMARY

In some arrangements, an electronic device includes an electronic component, an optical transceiver disposed over the electronic component, and an interposer disposed between the electronic component and the optical transceiver. The interposer is configured to reduce thermal interference to the optical transceiver.

In some arrangements, an electronic device includes an electronic component, an interconnection structure adjacent to the electronic component, and an interposer disposed over the electronic component and the interconnection structure. The electronic component is configured to receive a first electronic signal through the interconnection structure and the interposer, and to transmit a second electronic signal to an optical transceiver through the interposer.

In some arrangements, an electronic device includes a carrier having a heat dissipating region and a signal transmission region, an electronic component disposed over the heat dissipating region, and an interposer disposed over the electronic component. The signal transmission region is electrically connected with the electronic component through the interposer.

### BRIEF DESCRIPTION OF THE DRAWINGS

Aspects of some arrangements of the present disclosure are best understood from the following detailed description when read with the accompanying figures. It is noted that various structures may not be drawn to scale, and dimensions of the various structures may be arbitrarily increased or reduced for clarity of discussion.

FIG. 1A illustrates a cross-sectional view of an electronic device in accordance with some arrangements of the present disclosure.

FIG. 1B illustrates a cross-sectional view of an electronic device in accordance with some arrangements of the present disclosure.

FIG. 1C illustrates a cross-sectional view of an electronic device in accordance with some arrangements of the present disclosure.

FIG. 2A illustrates a cross-sectional view of a part of an electronic device in accordance with some arrangements of the present disclosure.

FIG. 2B illustrates a cross-sectional view of a part of an electronic device in accordance with some arrangements of the present disclosure.

FIG. 2C illustrates a cross-sectional view of a part of an electronic device in accordance with some arrangements of the present disclosure.

FIG. 2D illustrates a cross-sectional view of a part of an electronic device in accordance with some arrangements of the present disclosure.

FIG. 3A illustrates a cross-sectional view of an electronic device in accordance with some arrangements of the present disclosure.

FIG. 3B illustrates a cross-sectional view of an electronic device in accordance with some arrangements of the present disclosure.

FIG. 4 illustrates a cross-sectional view of an electronic device in accordance with some arrangements of the present disclosure.

FIG. 5A, FIG. 5B, FIG. 5C, FIG. 5D, FIG. 5E, and FIG. 5F illustrate cross-sectional views in one or more stages of a method of manufacturing an electronic device in accordance with an embodiment of the present disclosure.

### DETAILED DESCRIPTION

The following disclosure provides for many different arrangements, or examples, for implementing different features of the provided subject matter. Specific examples of components and arrangements are described as follows to explain certain aspects of the present disclosure. These are, of course, merely examples and are not intended to be limiting. For example, the formation of a first feature over or on a second feature in the description that follows may include arrangements in which the first and second features are formed or disposed in direct contact, and may also include arrangements in which additional features may be formed or disposed between the first and second features, such that the first and second features may not be in direct contact. In addition, the present disclosure may repeat reference numerals and/or letters in the various examples. This repetition is for the purpose of simplicity and clarity and does not in itself dictate a relationship between the various arrangements and/or configurations discussed.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of arrangements of this disclosure are not deviated from by such arrangement.

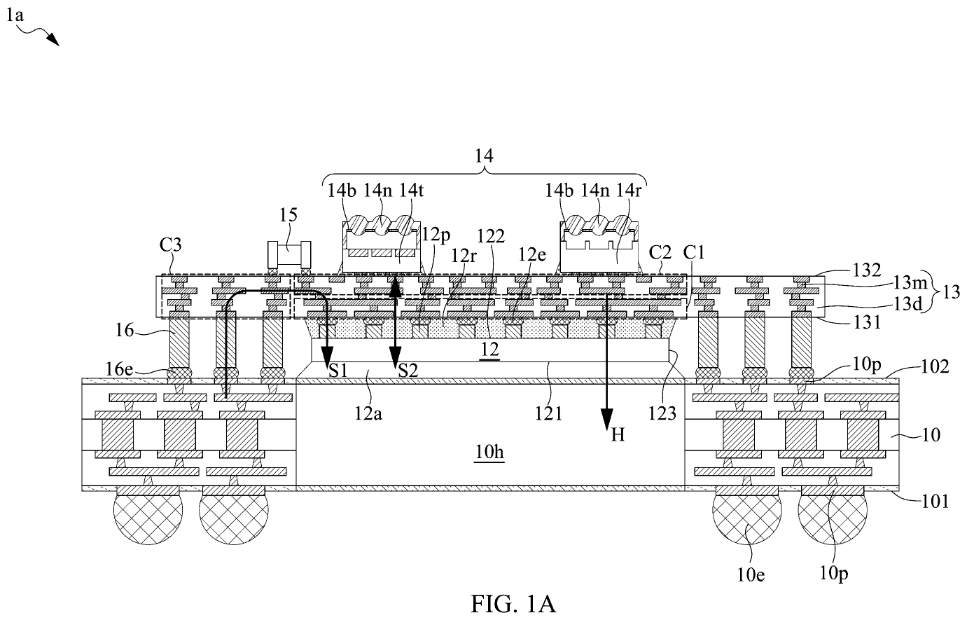

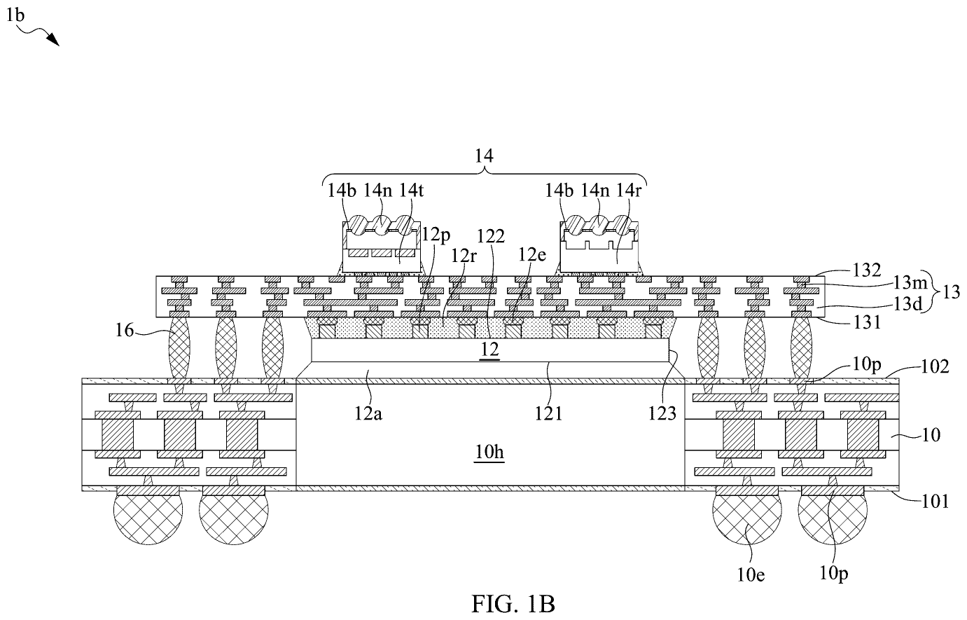

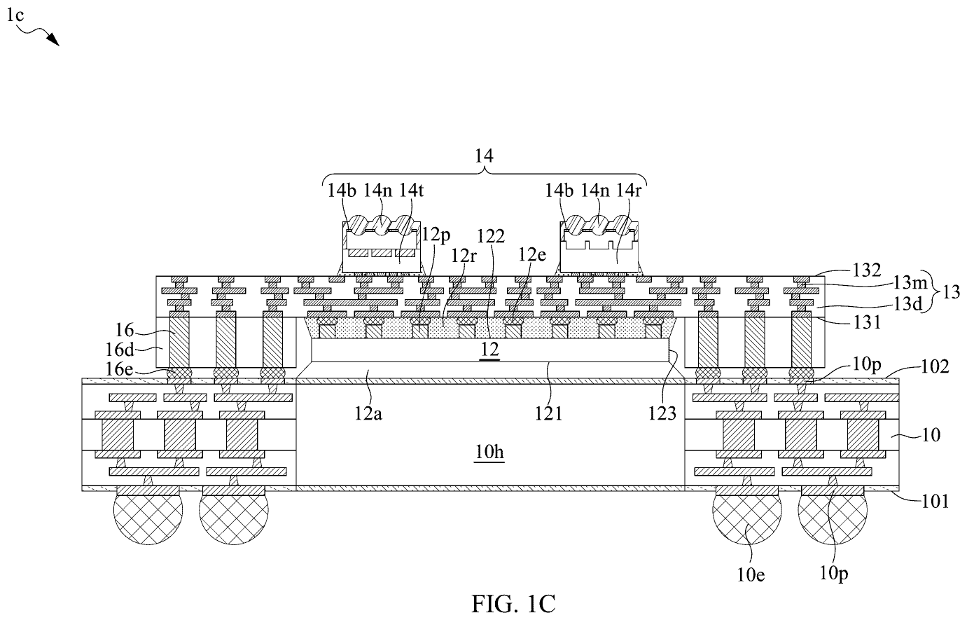

FIG. 1A illustrates a cross-sectional view of an electronic device 1a in accordance with some arrangements of the present disclosure.

In some arrangements, the electronic device 1a may include a package, such as a semiconductor device package. In some arrangements, the electronic device 1a may include carriers 10, 13, electronic components 12, 15, an optical component 14, and an interconnection structure 16.

The carrier 10 may include a substrate. In some arrangements, the carrier 10 may include, for example, a printed circuit board (PCB), such as a paper-based copper foil laminate, a composite copper foil laminate, or a polymer-impregnated glass-fiber-based copper foil laminate.

In some arrangements, the carrier 10 may include an interconnection structure or a circuit structure. The circuit structure may include a redistribution layer (RDL), a circuit layer, a conductive pillar, conductive pad, conductive trace, a conductive via, a conductive wire, or other conductive elements. The circuit structure may provide electrical connections for the components connected with the carrier 10.

The carrier 10 may include a surface 101 and a surface 102 opposite to the surface 101. The carrier 10 may include one or more conductive pads in proximity to, adjacent to, or embedded in and exposed by the surface 101 and/or the surface 102. The carrier 10 may include a solder resist on the surface 101 and/or the surface 102 to fully expose or expose at least a portion of the conductive pads for electrical connections. For example, the carrier 10 may include conductive pads 10p adjacent to the surface 101 and/or the surface 102 of the carrier 10.

In some arrangements, the carrier 10 may include a heat dissipating element 10h. The heat dissipating element 10h may be embedded or surrounded by the carrier 10. The heat dissipating element 10h may be provided at a substantially central portion of the carrier 10 from a cross-sectional view. The heat dissipating element 10h may be exposed by the surface 101 and/or the surface 102 of the carrier 10.

The heat dissipating element 10h may be disposed under the electronic component 12. In some arrangements, the heat dissipating element 10h may be connected to a surface (such as a backside surface) 121 of the electronic component 12 through an adhesive layer 12a, such as a heat dissipating gel. In some arrangements, in a direction substantially perpendicular to the surface 101 and/or the surface 102 of the carrier 10 (such as in a vertical direction), the electronic component 12 and the heat dissipating element 10h may be at least partially overlapped to facilitate heat dissipation for the electronic component 12. In some arrangements, in a direction substantially perpendicular to the surface 101 and/or the surface 102 of the carrier 10 (such as in a vertical direction), the optical component 14, the electronic component 12, and the heat dissipating element 10h may be at least partially overlapped to facilitate heat dissipation for the optical component 14.

The heat dissipating element 10h may include a relatively high thermal conductivity. For example, the heat dissipating element 10h may include copper (Cu), aluminum (Al), graphite, ceramics, etc. The heat dissipating element 10h may include a block, a pipe, a sink, a fin, or other shapes.

The heat dissipating element 10h may be configured to provide a heat dissipating path H. The heat dissipating element 10h may be configured to dissipate heat to external of the electronic device 1a. For example, a heat dissipating path H may be provided by the carrier 13, the electronic component 12, the adhesive layer 12a, and the heat dissipating structure 10h. Heat from a surface 122 (such as an active surface) of the electronic component 12 can be dissipated through the heat dissipating path H. Heat from the optical component 14 can be dissipated through the heat dissipating path H.

In some arrangements, the carrier 10 may include a heat dissipating region and a signal transmission region. The heat dissipating region may be or include the heat dissipating element 10h. The signal transmission region may be or include the circuit structure. The signal transmission region may surround the heat dissipating region. The signal transmission region may be at the periphery of the carrier 10.

In some arrangements, the carrier 10 may include an electrical contact 10e adjacent to the surface 101 for providing electrical connections between the electronic device 1a and an external device (e.g., a PCB, another electronic device, an electronic module, and so on).

In some arrangements, the electronic component 12 may be disposed over the carrier 10. In some arrangements, the electronic component 12 may be disposed over the heat dissipating region of the carrier 10. In some arrangements, the electronic component 12 may be disposed over the heat dissipating element 10h. In some arrangements, the electronic component 12 may be connected to the carrier 10 (or to the heat dissipating element 10h) through the adhesive layer 12a.

The electronic component 12 may include an active device or an active component. In some arrangements, the electronic component 12 may be or include circuits or circuit elements that rely on an external power supply to control or modify electronic signals. Examples of the active device may include an integrated circuit (IC), a chip, or a die that includes a semiconductor substrate, one or more integrated circuit devices and one or more overlying interconnection structures therein. For example, the electronic component 12 may include a controller, a processor, a central processing unit (CPU), a field-programmable gate array (FPGA), an application specific integrated circuit (ASIC), etc. The electronic component 12 may include a single chip or a plurality of chips.

In some arrangements, the electronic component 12 may include a surface 121 facing the carrier 10, a surface 122 opposite to the surface 121, and a lateral surface 123 extending between the surface 121 and the surface 122.

The surface 122 may be or include an active surface, a front surface, or a front side. The surface 121 may be or include a backside surface or a backside. Transistors and other active devices may be closer to the surface 122 then the surface 121.

The electronic component 12 may include a conductive pad 12p in proximity to, adjacent to, or embedded in and exposed by the surface 122. An electrical contact 12e may be disposed adjacent to the surface 122. The electronic component 12 may be electrically connected to one or more other electrical components (if any) and to the carrier 13, and the electrical connections may be attained by way of flip-chip (such as by utilizing the electrical contact 12e) or wire-bond techniques. The surface 122 may face and electrically connected with the carrier 13.

In some arrangements, a resin 12r may be disposed between the electronic component 12 and the carrier 13. The resin 12r may cover, surround or encapsulate the conductive pad 12p. The resin 12r may cover, surround or encapsulate the electrical contact 12e.

In some arrangements, a connection layer or a conductive paste can be used to connect the electronic component 12 and the carrier 13. For example, an epoxy solder paste can be used to form the electrical contact 12e. The epoxy solder paste may include a mixture of solder and epoxy resin. The epoxy solder paste is suitable for low-temperature bonding (around 150 degrees to 170 degrees), which reduces the stress generated by high temperatures. During the curing process, the solder may aggregate between the conductive pads, forming the electrical contact 12e and displacing the resin 12r. For example, the resin 12r may precipitate or separate from the electrical contact 12e. Additionally, the resin 12r may surround the electrical contact 12e, thereby eliminating the need for the underfill process. In some arrangements, the epoxy solder paste may include a Sn-Bi solder or a lead-free alloy with a low melting point.

In some arrangements, the electrical contact 12e and the resin 12r may be considered a connection layer that includes a conductive element and an encapsulant surrounding the conductive element. In some arrangements, the connection layer may be configured to connect the electronic component 12 and the carrier 13.

In some arrangements, the lateral surface 123 of the electronic component 12 may be exposed (such as entirely exposed or uncovered) from the resin 12r. In some other arrangements, the resin 12r may cover, surround or encapsulate a part of the lateral surface 123 of the electronic component 12. For example, in a direction (such as a horizontal direction) substantially parallel to the surface 101 and/or the surface 102 of the carrier 10, the resin 12r may be overlapped with the electronic component 12. In some arrangements, the resin 12r may entirely cover the lateral surface 123 of the electronic component 12.

The carrier 13 may be disposed over the surface 102 of the carrier 10. The carrier 13 may be disposed over the surface 122 of the electronic component 12. The carrier 13 may include a surface 131 facing the carrier 10 and a surface 132 opposite to the surface 131.

In some arrangements, the carrier 13 may include, for example, an interposer. In some arrangements, the carrier 13 may include interposer-like wirings to form a structure which may be regarded as an interposer or a fan-out substrate. In some arrangements, the carrier 13 may include metal 13m and dielectric 13d. The metal 13m may include a connector, such as a conductive terminal, a conductive layer, conductive pillar, conductive pad, conductive trace, a conductive via, a conductive wire, or another feasible connector. The dielectric 13d may include an epoxy resin having fillers, a molding compound (e.g., an epoxy molding compound or another molding compound), ajinomoto build-up film (ABF), etc. The dielectric 13d may include an opaque material, such as ink, carbon black, photoresist, or other non-transparent materials or low-transparent materials.

In some arrangements, the carrier 13 may include multiple layers. For example, the carrier 13 may include 2 to 4 metal layers (or conductive layers). For example, the carrier 13 may include 2 to 4 dielectric layers (or light blocking layers). The number of layers in the carrier 13 may be chosen based on the input/output (I/O) pins.

The carrier 13 may be disposed between the electronic component 12 and the optical component 14. For example, the carrier 13 may be configured to structurally support the optical component 14. The carrier 13 may be configured to provide electrical connections between the electronic component 12 and the optical component 14.

The carrier 13 may be configured to reduce or minimize thermal interference with the optical component 14, which is sensitive to temperature variations. Heat from the electronic component 12 or thermal coupling between the two can impact the performance, accuracy, and reliability of the optical component 14. By placing the carrier 13 between the electronic component 12 and the optical component 14, heat transfer can be blocked or dissipated.

In some arrangements, in a direction substantially perpendicular to the surface 101 and/or the surface 102 of the carrier 10 (such as in a vertical direction), the optical component 14, the electronic component 12, and the carrier 13 may be at least partially overlapped to enhance thermal insulation and reduce the effects of thermal variations.

In some arrangements, the carrier 13 may be configured to function as a light blocking structure. For example, the optical component 14 may include a transceiver having a transmitter 14t and a receiver 14r. The carrier 13 may be non-transmissive to the light emitted from the transmitter 14t. For example, the carrier 13 may be configured to block, reflect, scatter, or absorb the light emitted from the transmitter 14t. For example, the carrier 13 may be configured to prevent undesired light from being inadvertently detected by the receiver 14r. For example, the carrier 13 may be configured to reduce light crosstalk (optical signal crosstalk or optical crosstalk) between the transmitter 14t and the receiver 14r.

In some arrangements, the carrier 13 may include central portions C1, C2, and a peripheral portion C3. The central portion C1 may include a lower central portion adjacent to the surface 131, while the central portion C2 may include an upper central portion adjacent to the surface 132. The peripheral portion C3 may surround, encircle, or encompass the central portion C1. The peripheral portion C3 may surround, encircle, or encompass the central portion C2.

In some arrangements, the circuit density adjacent to the surface 131 may be relatively higher than that adjacent to the surface 132. For example, the circuit density of the central portion C1 may be relatively higher than that of the central portion C2. For example, the central portion C1 may include a higher-density circuit and the central portion C2 may include a lower-density circuit. For example, the line spacing and/or the pad pitch of the central portion C1 may be relatively narrower than that of the central portion C2.

In some arrangements, the lower-density circuit may be closer to the optical component 14 than the higher-density circuit. For example, the optical component 14 may be electrically connected with the surface 132, which has a lower circuit density than the surface 131.

In some arrangements, the higher-density circuit may be closer to the electronic component 12 than the lower-density circuit. For example, the electronic component 12 may be electrically connected with the surface 131, which has a higher circuit density than the surface 132.

In some arrangements, the circuit density in the center (or central portion) of the carrier 13 may be relatively higher than that in the periphery (or periphery portion) of the carrier 13. For example, the circuit density of the central portion C1 (or the central portion C2) may be relatively higher than that of the peripheral portion C3. For example, the central portion C1 (or the central portion C2) may include a higher-density circuit and the peripheral portion C3 may include a lower-density circuit. For example, the line spacing and/or the pad pitch of the central portion C1 (or the central portion C2) may be relatively narrower than that of the peripheral portion C3.

In some arrangements, the electronic component 12 and the optical component 14 may be electrically connected with the center (or central portion) of the carrier 13. In some arrangements, a passive component (such as the electronic component 15) may be electrically connected with the periphery (or periphery portion) of the carrier 13.

In some arrangements, the carrier 13 may include an overhang structure on one side of the electronic component 12. For example, the overhang structure of the carrier 13 may extend or protrude from a side of the electronic component 12. The carrier 13 may include a protruding structure on a side of the electronic component 12. The overhang structure or protruding structure may not be vertically overlapped by the electronic component 12. Additionally, the overhang structure or protruding structure may be located outside of the electronic component 12.

In some arrangements, the overhang structure may be or include the periphery (or periphery portion) of the carrier 13. In some arrangements, the overhang structure may include a lower-density circuit.

In some arrangements, in a direction substantially perpendicular to the surface 101 and/or the surface 102 of the carrier 10 (such as in a vertical direction), the overhang structure may be at least partially overlapped with the signal transmission region of the carrier 10. The overhang structure may be electrically connected with the signal transmission region of the carrier 10 through the interconnection structure 16.

In some arrangements, the optical component 14 may be disposed over and supported by the carrier 13. The optical component 14 may be separated from the carrier 10 by the carrier 13. The optical component 14 may be separated from the electronic component 12 by the carrier 13.

The optical component 14 may be electrically connected to one or more other electrical components (if any) and to the carrier 13, and the electrical connections may be attained by way of flip-chip (such as by utilizing an electrical contact) or wire-bond techniques. The optical component 14 may be electrically connected with the electronic component 12 through the carrier 13.

As mentioned, the optical component 14 may include a transceiver having the transmitter 14t and the receiver 14r. The transmitter 14t and the receiver 14r may be electrically connected with each other through the carrier 13.

The optical component 14 may be configured to support or provide the optical communication between the electronic device 1a and an external component. The optical component 14 may function as an optical transceiver and an optical interface that connects to an external component through a light carrying medium (which may include a fiber optic cable or an optical fiber). In some arrangements, the optical component 14 may include optical transmitters (such as the transmitter 14t), optical receivers (such as the receiver 14r), optical modulators, optical waveguides, optical splitters, optical combiners, optical grating couplers, etc.

In some arrangements, the transmitter 14t may include a light emitting diode (LED), a laser diode (such as vertical cavity surface-emitting laser (VCSEL)), a lamp, a laser, any other suitable light source, or a combination thereof. In some arrangements, the transmitter 14t may be arranged in an array (e.g., an LED array or a VCSEL array).

In some arrangements, the receiver 14r may include a photo-detector, a photo-sensor, a photodiode (PD), a charge-coupled device (CCD), a photomultiplier tube, a camera, a spectrometer, or another light-sensitive electronic device. In some arrangements, the receiver 14r may be arranged in an array (e.g., a PD array).

In some arrangements, the transmitter 14t may be referred to as a transmitting region and the receiver 14r may be referred to as a receiving region.

In some arrangements, the electronic component 12 may be configured to provide electronic functions for the optical component 14. More specifically, the electronic component 12 may be configured to control the optical component 14 and to process signals (including optical signals and electronic signals) sent to or received from the optical component 14.

In some arrangements, the electronic component 12 (e.g., an ASIC) may generate electronic signals for driving the optical component 14. The electronic signals may be communicated to the transmitter 14t (e.g., an LED), which outputs optical signals. The transmitter 14t may convert electronic signals into optical signals. For example, the electronic signals from the electronic component 12 may be transmitted through the carrier 13.

In some arrangements, optical signals from an optical source external to the electronic device 1a may be received by, for example, the receiver 14r (e.g., a PD). The receiver 14r may convert optical signals into electronic signals that are communicated to electronic component 12 to process (e.g., analysis, modify, synthesize, convert to a digital signal, and amplify, etc.), to store, and/or to transmit the electronic signals. For example, the electronic signals from the receiver 14r may be transmitted through the carrier 13. For example, the carrier 13 may provide, define, construct, or establish a signal transmission path S2 between the electronic component 12 and the optical component 14.

The optical component 14 may include an optical element 14n. The shape of the optical element 14n may be adjusted according to design requirements and is not intended to limit the present disclosure. For example, the optical element 14n may construct a panel, a waveguide, a prism, a concave lens, a convex lens, a flat surface, a diffuser, a shutter, a filter, a holographic element, etc.

In some arrangements, the optical element 14n may form a convex lens (or a concave-convex lens). The optical element 14n may include an extending portion extending from the convex lens to the transmitter 14t and the receiver 14r. The extending portion may support the convex lens.

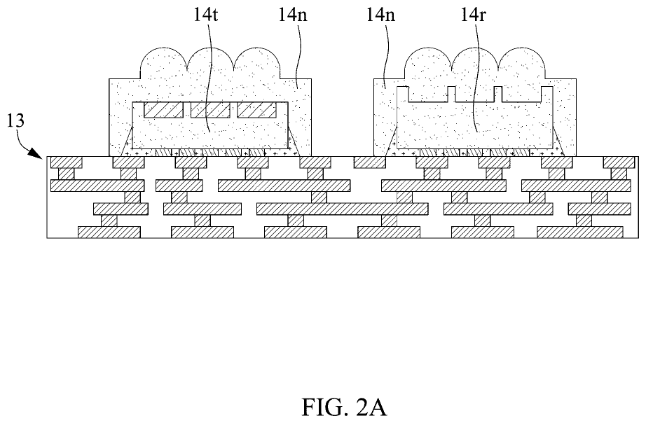

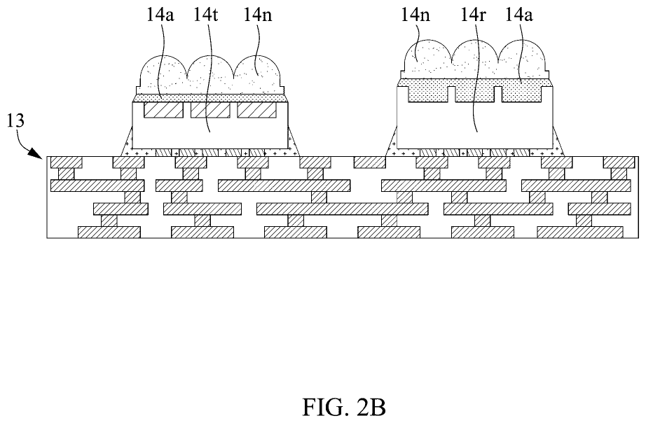

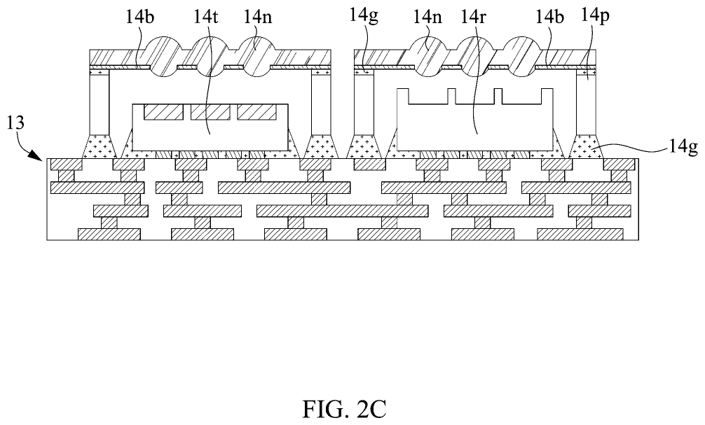

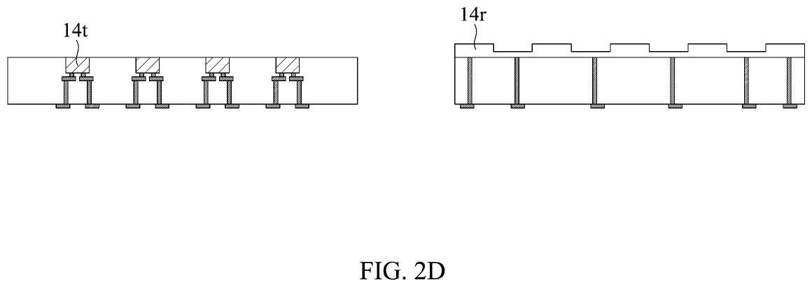

In some arrangements, the optical element 14n may contact (such as directly contact) the transmitter 14t and the receiver 14r. In some arrangements, the optical element 14n may be affixed, connected, or attached to the transmitter 14t and the receiver 14r through an adhesive layer (such as the adhesive layer 14g in FIG. 2C). For example, adhesive layer may be disposed on a corner of the optical element 14n. For example, the optical element 14n may include a corner or a recess portion configured to accommodate the adhesive layer.

A light blocking layer 14b may be disposed under the optical element 14n. The light blocking layer 14b may be disposed on planar portions of the optical element 14n, and the optical element 14n may include a convex profile among the light blocking layer 14b. For example, in a cross-sectional view, the convex surfaces may protrude from the light blocking layer 14b. The light blocking layer 14b may include an opaque material, such as ink, carbon black, photoresist, or other non-transparent materials or low transparent materials.

The electronic component 15 may include a passive component or a passive device. In some arrangements, the electronic component 15 may be circuits or circuit elements that do not need an external power source to function and do not provide electrical gain. Examples of the passive device may include an inductance device (or an inductor), a capacitance device (or capacitor), a resistor, a diode, a fuse, an antifuse, etc.

The positions, functions, and number of electronic components in the electronic device 1a are not intended to limit the present disclosure. For example, there may be any number of electronic components in the electronic device 1a due to design requirements. For example, the electronic component 15 (or a passive device) may be disposed over the carrier 10.

The interconnection structure 16 may be disposed adjacent to the electronic component 12. The interconnection structure 16 and the electronic component 12 may be disposed under the carrier 13. The carrier 13 may be disposed over the interconnection structure 16 and the electronic component 12. The electronic component 12 may be electrically connected with the central portion of the carrier 13, and the interconnection structure 16 may be electrically connected with the periphery portion of the carrier 13.

The interconnection structure 16 may be disposed between the carrier 10 and the carrier 13. The interconnection structure 16 may be disposed between the signal transmission region of the carrier 10 and the overhang structure of the carrier 13. The interconnection structure 16 may be electrically connected between the carrier 10 and the carrier 13. The interconnection structure 16 may be electrically connected between the signal transmission region of the carrier 10 and the overhang structure of the carrier 13. The interconnection structure 16 may be electrically connected with the carrier 10 through an electrical contact 16e.

In some arrangements, the electrical contacts 10e, 12e, and 16e may each include a reflowable conductive material, such as a soldering material. In some arrangements, the electrical contacts 10e, 12e, and 16e may each include one or more solder balls or solder bumps, such as a controlled collapse chip connection (C4) bump, a ball grid array (BGA) or a land grid array (LGA).

In some arrangements, the carrier 10 may receive external electronic signals. The carrier 10 may be configured to transmit the electronic signals to the interconnection structure 16. The electronic signals from the carrier 10 may be transmitted to the carrier 13, and to the electronic component 12, through the interconnection structure 16. The electronic component 12 may be configured to receive the electronic signals from the carrier 10 through the carrier 13 and the interconnection structure 16.

In some arrangements, the electronic component 12 may be configured to receive a first electronic signal through the carrier 13 and the interconnection structure 16, and to transmit a second electronic signal to the optical component 14 through the carrier 13.

In some arrangements, the electronic component 12 may be configured to receive a first electronic signal from the optical component 14 through the carrier 13, and to transmit a second electronic signal to carrier 10 through the carrier 13 and the interconnection structure 16.

In some arrangements, the carrier 10 and the carrier 13 may be electrically connected, and the electrical connections may be attained by the interconnection structure 16. For example, the interconnection structure 16 may provide, constitute, or establish a portion of a signal transmission path S1. In some arrangements, the carrier 10, the interconnection structure 16, the carrier 13, and the electronic component 12 may provide, constitute, or establish the signal transmission path S1.

The interconnection structure 16 may include conductive pillars. In some arrangements, the interconnection structure 16 may include conductive material such as metal or a metal alloy. Examples of the conductive material include gold (Au), silver (Ag), aluminum (Al), copper (Cu), platinum (Pt), Palladium (Pd), other metal(s) or alloy(s), or a combination of two or more thereof.

According to some arrangements of the present disclosure, utilizing the carrier 13 to connect the optical component 14 to the electronic component 12 allows for increased bandwidth without compromising package size. For example, a larger optical component or additional optical components 14 can be mounted on the carrier 13 without increasing the size of the electronic component 12. In addition, the carrier 13 can serve as a multi-functional interposer. This interposer can function as both a light-blocking structure and a thermal-blocking structure. Overall, the issues related to light and thermal influence on optical component 14 can be addressed, and the bandwidth requirements can be met.

FIG. 1B and FIG. 1C illustrate cross-sectional views of an electronic device 1b and an electronic device 1c in accordance with some arrangements of the present disclosure. The electronic device 1b in FIG. 1B is similar to the electronic device 1a in FIG. 1A except that the interconnection structure 16 includes solder balls. The electronic device 1c in FIG. 1C is similar to the electronic device 1a in FIG. 1A except that the electronic device 1c further includes a dielectric surrounding the interconnection structure 16.

In some arrangements, the interconnection structure 16 may include conductors of other shapes or configurations, such as wires, wire bundles, cables, metal blocks, rods, rails, pipes, etc.

FIG. 2A, FIG. 2B, FIG. 2C, and FIG. 2D illustrates cross-sectional views of a part of an electronic device in accordance with some arrangements of the present disclosure.

In FIG. 2A, the optical element 14n may cover, surround, or encapsulate the transmitter 14t and the receiver 14r. The optical element 14n may include a convex profile over the tops of the transmitter 14t and the receiver 14r.

In FIG. 2B, the optical element 14n may be affixed, connected, or attached to the transmitter 14t and the receiver 14r through an adhesive layer 14a. The adhesive layer 14a may include a light transmissive material, such as clear glass, clear plastic, clear gel, clear resin, clear epoxy, sapphire, or other transparent materials. The adhesive layer 14a may be transparent to the light emitted from the transmitter 14t. The adhesive layer 14a may be transparent to the light detected by the receiver 14r.

In FIG. 2C, the optical component 14 may include a partition 14p. The partition 14p may include a wall, a pillar, a shielding structure, a light blocking structure, etc. The partition 14p may be disposed over the carrier 13. The partition 14p may be affixed, connected, or attached to the carrier 13 through an adhesive layer 14g. The adhesive layer 14g may be disposed on a corner of the partition 14p. For example, the partition 14p may include a corner or a recess portion configured to accommodate the adhesive layer 14g. The adhesive layer 14g may include epoxy, resin, or other suitable materials, and may be a paste. The adhesive layer 14g may be thermally and/or optically cured. In some arrangements, the adhesive layer 14g may be non-transmissive or low-transmissive to the light emitted from the transmitter 14t. For example, the adhesive layer 14g may include an opaque material, such as ink, carbon black, photoresist, or other non-transmissive or low-transmissive materials.

The partition 14p may encircle or surround the transmitter 14t and the receiver 14r. The partition 14p may separate or isolate the transmitter 14t from the receiver 14r.

The partition 14p may be configured to function as a light blocking structure. For example, the partition 14p may be non-transmissive or low-transmissive to the light emitted from the transmitter 14t. For example, the partition 14p may be configured to block, reflect, scatter, or absorb the light emitted from the transmitter 14t. For example, the partition 14p may be configured to prevent undesired light from being inadvertently detected by the receiver 14r. For example, the partition 14p may be configured to reduce light crosstalk between the transmitter 14t and the receiver 14r.

In some arrangements, the carrier 13, the partition 14p, and/or the adhesive layer 14g may together form or constitute a light blocking structure.

In some arrangements, the optical element 14n may be affixed, connected, or attached to the partition 14p through the adhesive layer 14g. The optical element 14n may contact the adhesive layer 14g. In some arrangements, the light blocking layer 14b may be affixed, connected, or attached to the partition 14p through the adhesive layer 14g. The light blocking layer 14b may contact the adhesive layer 14g.

The optical component 14 in FIG. 1A may be replaced with the structures in FIG. 2A, FIG. 2B, and FIG. 2C.

In FIG. 2D, the transmitter 14t may include an LED array integrated as a component. The receiver 14r may include a PD array integrated as a component.

The arrangement, profile, or contour of the optical element 14n may be adjusted based on designed requirements and is not limited thereto. In addition, the structures of the transmitter 14t and the receiver 14r may be adjusted based on designed requirements and is not limited thereto.

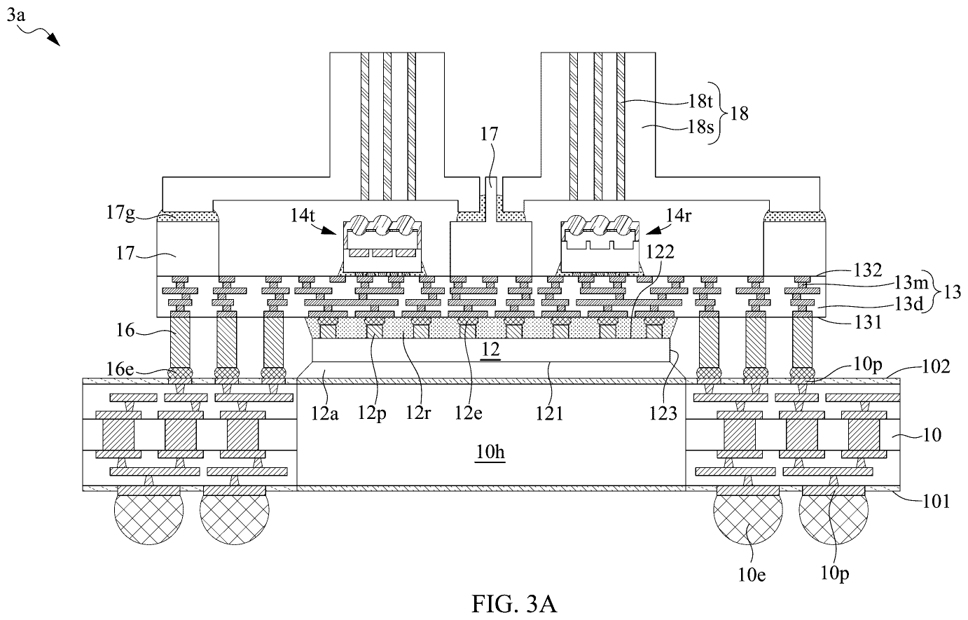

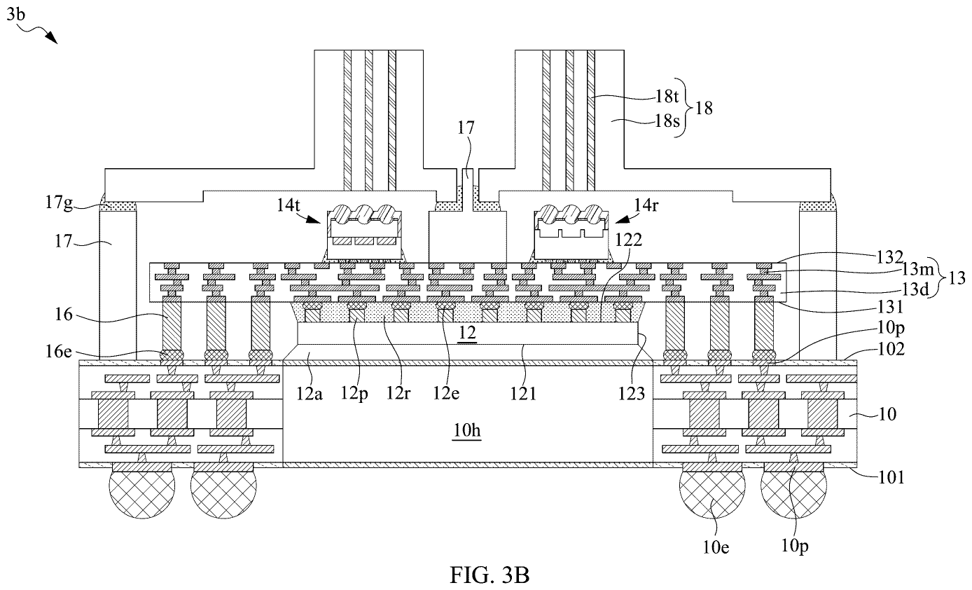

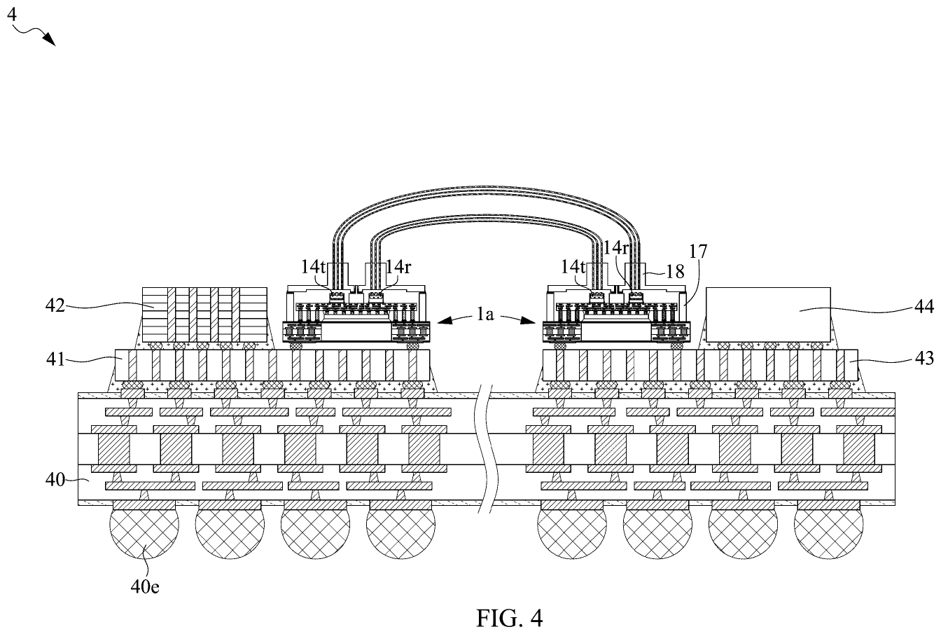

FIG. 3A illustrates a cross-sectional view of an electronic device 3a in accordance with some arrangements of the present disclosure. The electronic device 3a in FIG. 3A is similar to the electronic device 1a in FIG. 1A except that the electronic device 3a further includes a supporting area 17 and a light carrying medium 18.

The supporting area 17 may be disposed over the carrier 13. In some arrangements, the supporting area 17 may be affixed, connected, or attached to the carrier 13 through an adhesive layer (not shown in the figures). The adhesive layer may provide the necessary bond between the supporting area 17 and the carrier 13. The adhesive layer may be a thermosetting epoxy, a silicone-based adhesive layer, an optical adhesive layer, etc.

The supporting area 17 may include a fiber array supporting area. For example, the supporting area 17 may be configured to support the light carrying medium 18. The supporting area 17 may surround the optical component 14. The supporting area 17 may be disposed over the interconnection structure 16. The supporting area 17 may be separated from the interconnection structure 16 by the carrier 13.

From a cross-sectional view, the supporting area 17 may include three parts: two are located on opposite sides of the carrier 13, and one is positioned between the transmitter 14t and the receiver 14r. A portion of the supporting area 17 may contact (such as directly contact) the carrier 13.

The light carrying medium 18 may be affixed, connected, or attached to the supporting area 17 through an adhesive layer 17g, which may have the same properties as the adhesive layer 14g in FIG. 2C.

The light carrying medium 18 may be supported over the optical component 14 by the supporting area 17.

The light carrying medium 18 may include an optical component. For example, the light carrying medium 18 may include an outer sheath 18s and multiple light paths (or light lanes) 18t. The light paths 18t may be aligned with the optical element 14n to couple optical signals from the transmitter 14t into the light carrying medium 18. The light paths 18t may be aligned with the optical element 14n to couple optical signals from the light carrying medium 18 into the receiver 14r.

In some arrangements, the light carrying medium 18 may include an array. The array of light carrying mediums 18 may, for example, be an M×N array of light paths 18t. For example, the light paths 18t may be arranged on a two dimensional (2D) surface. For example, the light paths 18t may be arranged along at least two dimensions or directions.

FIG. 3B illustrates a cross-sectional view of an electronic device 3b in accordance with some arrangements of the present disclosure. The electronic device 3b in FIG. 3B is similar to the electronic device 3a in FIG. 3A except that the supporting area 17 may be disposed over the carrier 10 and may surround the carrier 13.

The supporting area 17 may be disposed over the carrier 10. In some arrangements, the supporting area 17 may be affixed, connected, or attached to the carrier 10 through an adhesive layer (not shown in the figures). The adhesive layer may provide the necessary bond between the supporting area 17 and the carrier 10. The adhesive layer may be a thermosetting epoxy, a silicone-based adhesive layer, an optical adhesive layer, etc.

In some arrangements, a portion of the supporting area 17 may contact (such as directly contact) the carrier 10. The supporting area 17 may be adjacent to the interconnection structure 16.

FIG. 4 illustrates a cross-sectional view of an electronic device 4 in accordance with some arrangements of the present disclosure.

In some arrangements, the electronic device 4 may include a system-in-package (SiP) module. The electronic device 4 may include the electronic device 1a, carriers 40, 41, 43, electronic components 42, 44, the supporting area 17, and the light carrying medium 18.

The electronic devices 1a may be disposed over the carrier 41 and the carrier 43. The detailed properties and characteristics of the electronic device 1a are similar to those of FIG. 1A and will not be repeated here for conciseness. The electronic device 1a may be replaced by the electronic device 1b or the electronic device 1c.

In some arrangements, the electronic device 1a may be supported by the carrier 40. For example, the carrier 41 may support the electronic component 42, and the electronic device 1a is directly connected to the carrier 40.

The supporting area 17 and the light carrying medium 18 may be disposed over the electronic device 1a. In some arrangements, the supporting area 17 may be disposed over the carrier 41 and surround the electronic devices 1a. The supporting area 17 may be disposed over the carrier 43 and surround the electronic devices 1a.

The light carrying medium 18 may connect between two electronic devices 1a to facilitate the propagation of light waves. For example, an optical signal emitted from the transmitter 14t of the electronic devices 1a on the left may be transmitted to the receiver 14r of the electronic devices 1a on the right through the light carrying medium 18. Similarly, an optical signal emitted from the transmitter 14t of the electronic devices 1a on the right may be transmitted to the receiver 14r of the electronic devices 1a on the left through the light carrying medium 18.

The detailed properties and characteristics of the carrier 40 are similar to those of the carrier 10 and will not be repeated here for conciseness. In some arrangements, the carrier 40 may include an electrical contact 40e for providing electrical connections between the electronic device 4 and an external device (e.g., a PCB, an electronic device, an electronic module, and so on).

The carrier 41 and the carrier 43 may each include a silicon interposer. In some arrangements, the carrier 41 and the carrier 43 may each connect multiple chips (such as the electronic component 12) in a 2.5D packaging architecture. The carrier 41 and the carrier 43 may each include a substrate having a silicon material, and a plurality of vias. The vias may include through silicon vias (TSV) for vertical interconnections.

In some arrangements, the electronic component 42 may include a non-volatile memory (such as a flash memory and a read-only memory (ROM)) or a volatile memory (such as a Dynamic Random Access Memory (DRAM)). In some arrangements, the active component 42 may include a high bandwidth memory (HBM).

The detailed properties and characteristics of the electronic component 44 are similar to those of the electronic component 12 and will not be repeated here for conciseness.

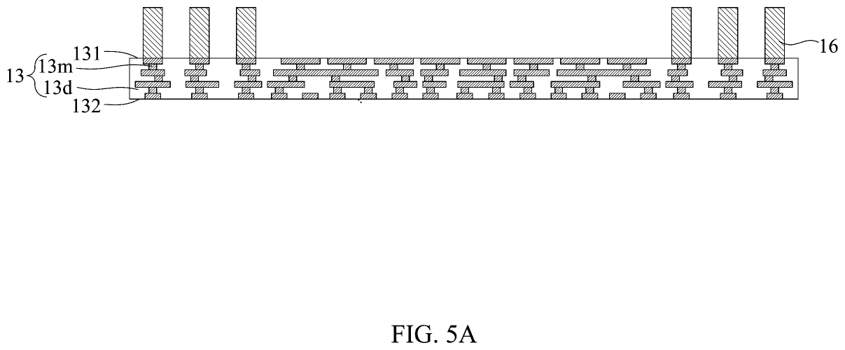

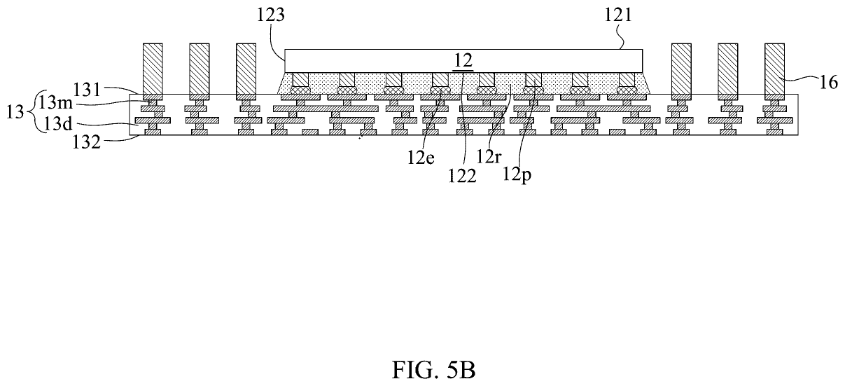

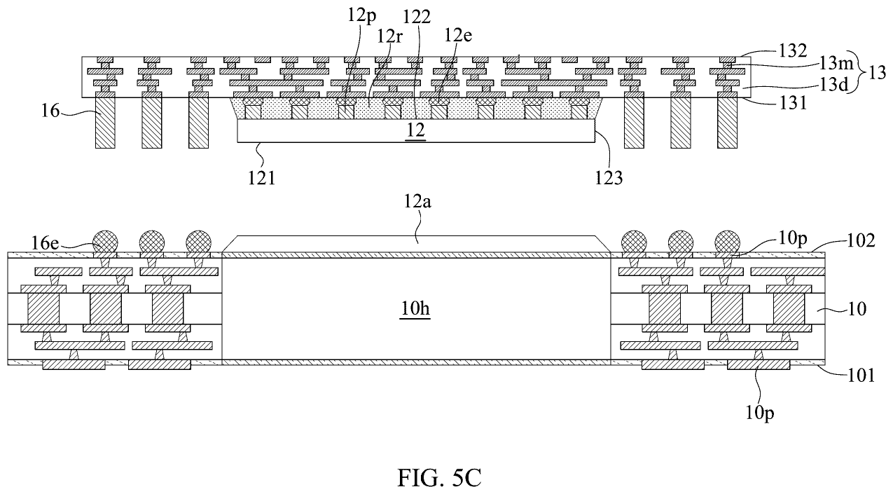

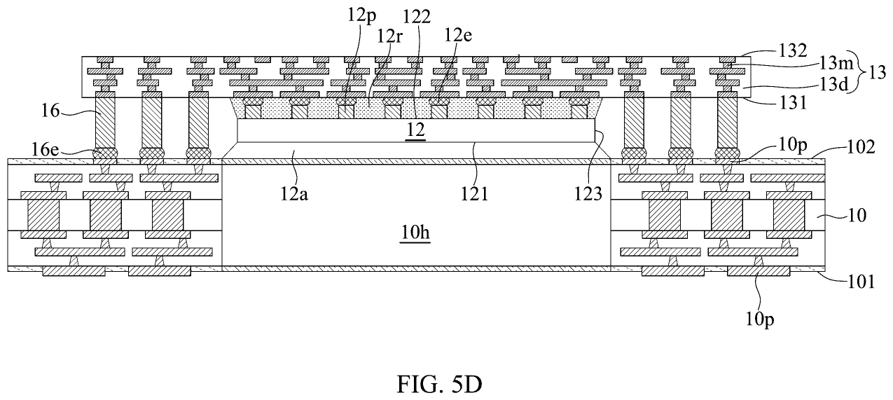

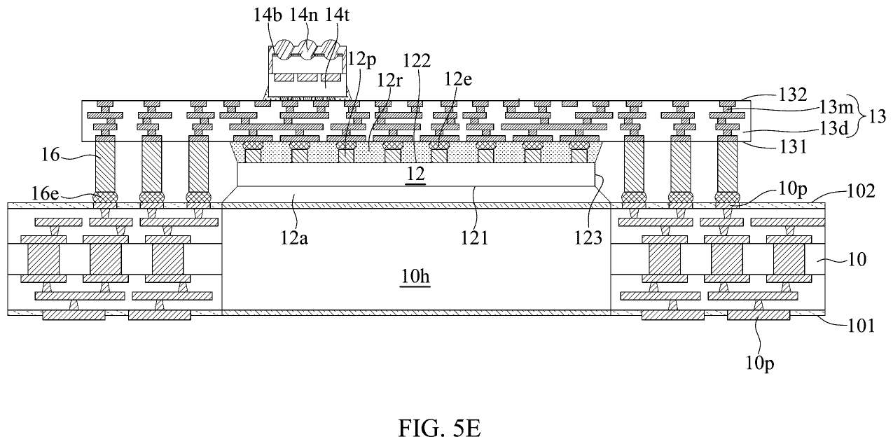

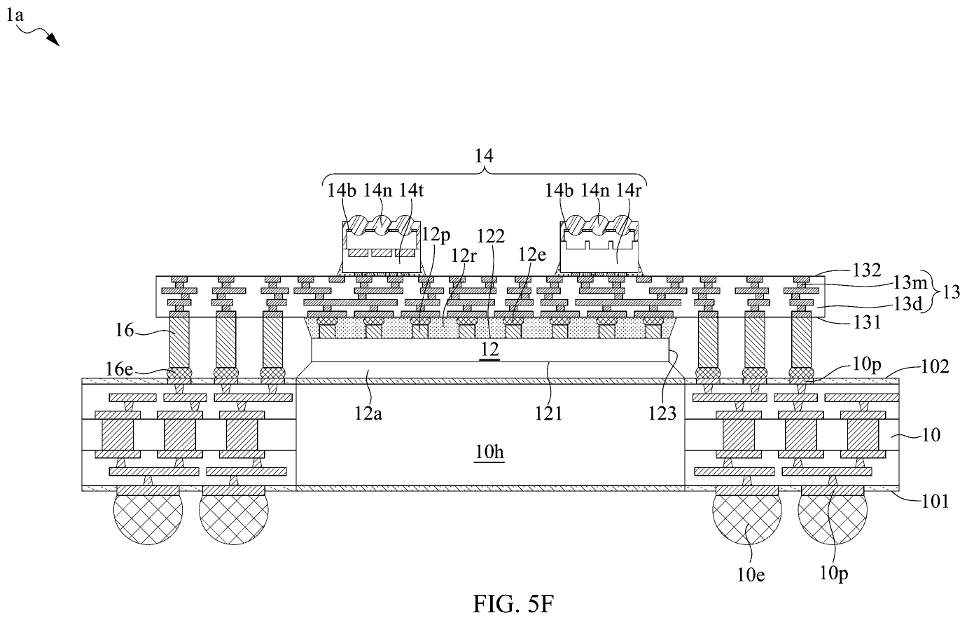

FIG. 5A, FIG. 5B, FIG. 5C, FIG. 5D, FIG. 5E, and FIG. 5F illustrate cross-sectional views in one or more stages of a method of manufacturing an electronic device in accordance with an embodiment of the present disclosure. At least some of these figures have been simplified to better understand the aspects of the present disclosure. In some arrangements, the electronic device 1a may be manufactured through the steps illustrated in FIG. 5A, FIG. 5B, FIG. 5C, FIG. 5D, FIG. 5E, and FIG. 5F.

Referring to FIG. 5A, the carrier 13 may be provided. The carrier 13 may include the surface 131 and the surface 132 opposite to the surface 131. The interconnection structure 16 may be disposed over the surface 131. The interconnection structure 16 may be electrically connected with the carrier 13, such as the periphery portion of the carrier 13.

Referring to FIG. 5B, a material (such as the epoxy solder paste) of the electrical contact 12e may be disposed over the surface 131. The epoxy solder paste may be spaced apart from the interconnection structure 16. The electronic component 12 may be disposed over the epoxy solder paste. The surface (such as an active surface) 122 of the electronic component 12 may be connected to the epoxy solder paste. The electronic component 12 may be disposed adjacent to the interconnection structure 16.

A curing operation may be conducted to melt the epoxy solder paste, forming the electrical contact 12e. The electronic component 12 may be electrically connected with the carrier 13, such as the central portion of the carrier 13. The electronic component 12 may be electrically connected with the carrier 13 through the electrical contact 12e.

Referring to FIG. 5C, the carrier 10 may be provided. The carrier 10 may include the surface 101 and the surface 102 opposite to the surface 101. The carrier 10 may include the heat dissipating element 10h. The carrier 10 may include a heat dissipating region and a signal transmission region. The heat dissipating region may be or include the heat dissipating element 10h. The signal transmission region may be or include the circuit structure. The electrical contact 16e may be disposed over the signal transmission region of the carrier 10. The adhesive layer 12a may be disposed over the heat dissipating region of the carrier 10.

Referring to FIG. 5D, the structure obtained from the operation in FIG. 5B may be disposed over the carrier 10. For example, the interconnection structure 16 may be electrically connected with the carrier 10 through the electrical contact 16e. For example, the surface (such as a backside surface) 121 of the electronic component 12 may be connected to the heat dissipating element 10h through the adhesive layer 12a.

Referring to FIG. 5E, the transmitter 14t may be disposed over the carrier 13. The transmitter 14t may be electrically connected with the carrier 13. The transmitter 14t may be electrically connected with the electronic component 12 through the carrier 13.

Referring to FIG. 5F, the receiver 14r may be disposed over the carrier 13. The receiver 14r may be electrically connected with the carrier 13. The receiver 14r may be electrically connected with the electronic component 12 through the carrier 13.

A singulation may be performed to separate out individual electronic device 1a. The singulation may be performed, for example, by using a dicing saw, laser or other appropriate cutting techniques. In some arrangements, an optical test may be conducted.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of arrangements of this disclosure are not deviated from by such an arrangement.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, a first numerical value can be deemed to be “substantially” the same or equal to a second numerical value if the first numerical value is within a range of variation of less than or equal to ±10% of the second numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, “substantially” perpendicular can refer to a range of angular variation relative to 90°that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°.

Two surfaces can be deemed to be coplanar or substantially coplanar if a displacement between the two surfaces is no greater than 5 μm, no greater than 2 μm, no greater than 1 μm, or no greater than 0.5 μm. A surface can be deemed to be substantially flat if a displacement between a highest point and a lowest point of the surface is no greater than 5 μm, no greater than 2 μm, no greater than 1 μm, or no greater than 0.5 μm.

As used herein, the singular terms “a,” “an,” and “the” may include plural referents unless the context clearly dictates otherwise.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 104 S/m, such as at least 105 S/m or at least 106 S/m. The electrical conductivity of a material can sometimes vary with temperature. Unless otherwise specified, the electrical conductivity of a material is measured at room temperature.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific arrangements thereof, these descriptions and illustrations are not limiting. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other arrangements of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. An electronic device, comprising:
an electronic component;
an optical transceiver disposed over the electronic component; and
an interposer disposed between the electronic component and the optical transceiver,
wherein the interposer is configured to reduce thermal interference to the optical transceiver.

2. The electronic device of claim 1, wherein the interposer includes a lower-density circuit region and a higher-density circuit region, wherein the lower-density circuit region is closer to the optical transceiver than the higher-density circuit region.

3. The electronic device of claim 1, wherein the interposer includes a first surface facing the electronic component and a second surface opposite to the first surface, and wherein a circuit density closer to the second surface is lower than a circuit density closer to the first surface.

4. The electronic device of claim 3, wherein the optical transceiver is electrically connected with the second surface, and the electronic component is electrically connected with the first surface.

5. The electronic device of claim 1, wherein the interposer includes a central portion and a periphery portion, and wherein a circuit density in the periphery portion is lower than a circuit density in the central portion.

6. The electronic device of claim 5, wherein the optical transceiver and the electronic component are electrically connected with the central portion.

7. The electronic device of claim 6, further comprising:
a passive component electrically connected with the periphery portion.

8. The electronic device of claim 6, further comprising:
a carrier; and
an interconnection structure electrically connected between the periphery portion and the carrier.

9. The electronic device of claim 8, wherein the carrier includes a heat dissipating element connecting with a backside surface of the electronic component.

10. The electronic device of claim 1, wherein the optical transceiver includes a light emitting diode (LED) array.

11. The electronic device of claim 10, wherein the optical transceiver includes a photodiode (PD) array.

12. The electronic device of claim 1, wherein the interposer includes an overhang structure on a side of the electronic component.

13. The electronic device of claim 1, wherein the optical transceiver includes a transmitting region and a receiving region, and wherein the interposer is configured to reduce light crosstalk between the transmitting region and the receiving region.

14. An electronic device, comprising:
an electronic component;
an interconnection structure adjacent to the electronic component; and
an interposer disposed over the electronic component and the interconnection structure,
wherein the electronic component is configured to receive a first electronic signal through the interconnection structure and the interposer, and to transmit a second electronic signal to an optical transceiver through the interposer.

15. The electronic device of claim 14, wherein the electronic component, the interposer, and the optical transceiver are at least partially overlapped.

16. The electronic device of claim 14, wherein a backside surface of the electronic component is connected to a heat dissipating element, and wherein the heat dissipating element, the electronic component, and the optical transceiver are at least partially overlapped.

17. The electronic device of claim 16, wherein the heat dissipating element is embedded in a carrier configured to transmit the first electronic signal to the interconnection structure.

18. An electronic device, comprising:
a carrier having a heat dissipating region and a signal transmission region;
an electronic component disposed over the heat dissipating region; and
an interposer disposed over the electronic component,
wherein the signal transmission region is electrically connected with the electronic component through the interposer.

19. The electronic device of claim 18, further comprising:
an optical transceiver disposed over the interposer, wherein the optical transceiver is electrically connected with the electronic component through the interposer.

20. The electronic device of claim 19, wherein a heat dissipating path for the optical transceiver is provided by the interposer, the electronic component, and the heat dissipating region.
